(19) United States
(12) Patent Application Publication
(10) Pub. No.: US 2026/0309477 A1
(43) Pub. Date: Oct. 8, 2026

(54) MAGNETIC SENSOR SYSTEM AND POSITION DETECTION DEVICE

(71) Applicant: TDK Corporation, Tokyo (JP)

(72) Inventors: Junichi OZEKI, Tokyo (JP); Kentaro HARADA, Tokyo (JP)

(73) Assignee: TDK Corporation, Tokyo (JP)

(21) Appl. No.: 19/640,484

(22) Filed: Apr. 7, 2026

(30) Foreign Application Priority Data
Apr. 8, 2025 (JP) 2025-063637

(51) Int. Cl. G01B 7/00; G01R 33/00; G01R 33/038

(52) U.S. Cl. CPC G01B 7/003; G01R 33/0047; G01R 33/038

(57) ABSTRACT

A magnetic sensor system includes a magnetic field generating body configured to generate a target magnetic field, and a magnetic sensor configured to detect the target magnetic field at a detection position. The magnetic field generating body and the magnetic sensor are arrayed in a first direction, and are configured so that a relative position of the magnetic field generating body with respect to the magnetic sensor varies in a second direction. As viewed in the first direction, the detection position is a position overlapping with the magnetic field generating body, and is a position away from both ends of the magnetic field generating body in a third direction. The magnetic field generating body is configured so that the target magnetic field includes a component in the third direction at the detection position. The magnetic sensor has sensitivity in the third direction.

### CROSS REFERENCE TO RELATED APPLICATIONS

This application claims the benefit of Japanese Priority Patent Application No. 2025-063637 filed on Apr. 8, 2025, the entire contents of which are incorporated herein by reference.

### BACKGROUND

The disclosure relates to a magnetic sensor system including a magnetic field generating body and a magnetic sensor, and a position detection device using the magnetic sensor system.

Position detection devices using magnetic sensors have been used for a variety of applications. Hereinafter, the position detection devices using magnetic sensors are referred to as magnetic position detection devices. For example, the magnetic position detection devices are used for detecting a lens position in a camera module having an optical image stabilization mechanism and an autofocus mechanism that are incorporated in a smartphone.

A magnetic position detection device includes, for example, a magnet that moves in conjunction with movement of a target object, and a magnetic sensor that detects a magnetic field generated by the magnet. Examples of such a device are described in JP 2013-246134 A and WO 2007/049639.

JP 2013-246134 A describes a position detection device including one or two magnets arranged to be movable in a detection axis direction, and a Hall sensor that detects a magnetic flux density generated by the one or two magnets. The Hall sensor faces a gap between the two magnets or a recess provided in the one magnet.

WO 2007/049639 describes a position detection device including a magnet and a magnetic field intensity sensor that detects a magnetic field in a normal direction of a surface of the magnet. The magnetic field intensity sensor faces a non-magnetic region provided between an N pole and an S pole or a low-magnetic region that is a groove portion provided in a central portion of the magnet.

As a driving device for a position detection device having an optical image stabilization mechanism, a driving device configured by a magnet and a coil is known. The magnet and the coil are arranged, for example, so as to be aligned in a vertical direction, which is a direction perpendicular to a substrate on which a magnetic sensor is fixed. The magnet is fixed to a holding member that holds a lens and is movable in a horizontal direction, which is a direction orthogonal to the vertical direction. In such a position detection device, when a current flows through the coil, a magnetic field in the vertical direction is generated from the coil, and the holding member moves in the horizontal direction due to interaction between a magnetic field generated from the magnet and the magnetic field generated from the coil.

The magnetic sensor and the magnet are arranged so as to be aligned in the vertical direction. When a magnetic sensor having sensitivity in the vertical direction is used, such as the magnetic sensors described in JP 2013-246134 A and WO 2007/049639, a magnetic field generated from the coil is superposed on a magnetic field generated from the magnet. As a result, there has been a case where detection accuracy of a position of the magnet is degraded.

### SUMMARY

A magnetic sensor system according to one embodiment of the disclosure includes a magnetic field generating body configured to generate a target magnetic field, and a magnetic sensor configured to detect the target magnetic field at a detection position. The magnetic field generating body and the magnetic sensor are arrayed in a first direction, and are configured so that a relative position of the magnetic field generating body with respect to the magnetic sensor varies in a second direction intersecting with the first direction. As viewed in the first direction, the detection position is a position overlapping with the magnetic field generating body, and is a position away from both ends of the magnetic field generating body in a third direction intersecting with each of the first direction and the second direction. The magnetic field generating body is configured so that the target magnetic field includes a component in the third direction at the detection position. The magnetic sensor has sensitivity in the third direction.

A position detection device according to one embodiment of the disclosure is a position detection device for detecting a position of a target object whose position is variable. The position detection device according to one embodiment of the disclosure includes a magnetic sensor system including a magnetic field generating body configured to generate a target magnetic field and a magnetic sensor configured to detect the target magnetic field at a detection position, and the target object. The magnetic field generating body and the magnetic sensor are arrayed in a first direction, and are configured so that a relative position of the magnetic field generating body with respect to the magnetic sensor varies in a second direction intersecting with the first direction. The relative position of the magnetic field generating body with respect to the magnetic sensor has a correspondence with the target object. As viewed in the first direction, the detection position is a position overlapping with the magnetic field generating body, and is a position away from both ends of the magnetic field generating body in a third direction intersecting with each of the first direction and the second direction. The magnetic field generating body is configured so that the target magnetic field includes a component in the third direction at the detection position. The magnetic sensor has sensitivity in the third direction.

Objects, features, and advantages of the disclosure appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a perspective view illustrating a camera module including a magnetic sensor system according to a first example embodiment of the disclosure.

FIG. 2 is a schematic explanatory view illustrating an internal of the camera module illustrated in FIG. 1.

FIG. 3 is a perspective view illustrating a driving device in the first example embodiment of the disclosure.

FIG. 4 is a perspective view illustrating a plurality of coils of the driving device illustrated in FIG. 3.

FIG. 5 is a perspective view illustrating the magnetic sensor system according to the first example embodiment of the disclosure.

FIG. 6 is a side view illustrating the magnetic sensor system according to the first example embodiment of the disclosure.

FIG. 7 is a side view illustrating the magnetic sensor system according to the first example embodiment of the disclosure.

FIG. 8 is a circuit diagram illustrating a circuit configuration of a magnetic sensor in the first example embodiment of the disclosure.

FIG. 9 is a perspective view illustrating a part of one resistor section in FIG. 8.

FIG. 10 is a perspective view illustrating a magnetoresistive element in the first example embodiment of the disclosure.

FIG. 11 is a perspective view illustrating a magnetic field generating body in the first example embodiment of the disclosure.

FIG. 12 is a plan view illustrating the magnetic field generating body in the first example embodiment of the disclosure.

FIG. 13 is a perspective view illustrating a magnetic field generating body in a comparative example.

FIG. 14 is a characteristic chart showing results of a first simulation.

FIG. 15 is a characteristic chart showing results of a second simulation.

FIG. 16 is a characteristic chart showing a third component in the first simulation and a third component in the second simulation.

FIG. 17 is a characteristic chart showing a detection signal obtained by a third simulation.

FIG. 18 is a characteristic chart showing crosstalk obtained by the third simulation.

FIG. 19 is a perspective view illustrating a magnetic field generating body in a first modification example in the first example embodiment of the disclosure.

FIG. 20 is a perspective view illustrating a magnetic field generating body in a second modification example in the first example embodiment of the disclosure.

FIG. 21 is a perspective view illustrating a magnetic field generating body in a third modification example in the first example embodiment of the disclosure.

FIG. 22 is a perspective view illustrating a magnetic field generating body in a fourth modification example in the first example embodiment of the disclosure.

FIG. 23 is a perspective view illustrating a magnetic field generating body in a fifth modification example in the first example embodiment of the disclosure.

FIG. 24 is a perspective view illustrating a magnetic field generating body in a sixth modification example in the first example embodiment of the disclosure.

FIG. 25 is a perspective view illustrating a magnetic field generating body in a seventh modification example in the first example embodiment of the disclosure.

FIG. 26 is a perspective view illustrating a magnetic sensor system according to a second example embodiment of the disclosure.

FIG. 27 is a side view illustrating the magnetic sensor system according to the second example embodiment of the disclosure.

FIG. 28 is a circuit diagram illustrating a circuit configuration of the magnetic sensor system according to the second example embodiment of the disclosure.

FIG. 29 is a circuit diagram illustrating a modification example of the circuit configuration of the magnetic sensor system according to the second example embodiment of the disclosure.

### DETAILED DESCRIPTION

An object of the disclosure is to provide a magnetic sensor system capable of detecting a target magnetic field without being affected by a magnetic field other than the target magnetic field, and a position detection device including the magnetic sensor system.

In the following, some example embodiments and modification examples of the disclosure will be described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions. The description is given in the following order.

### First Example Embodiment

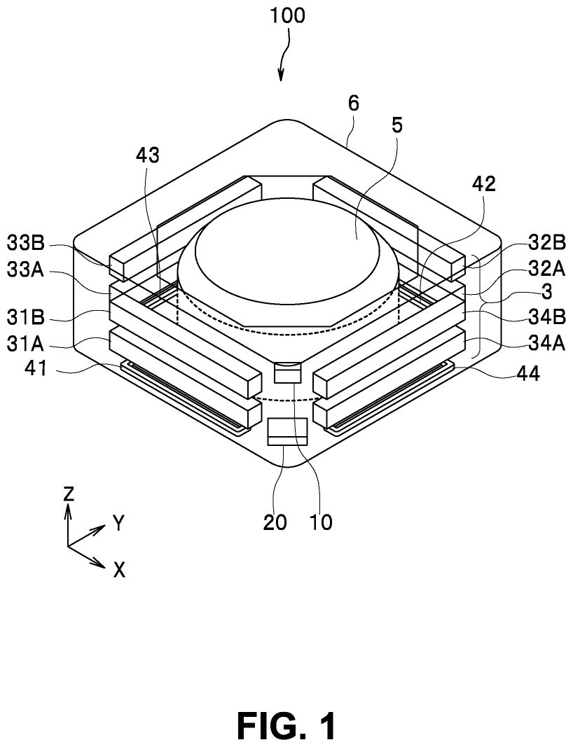

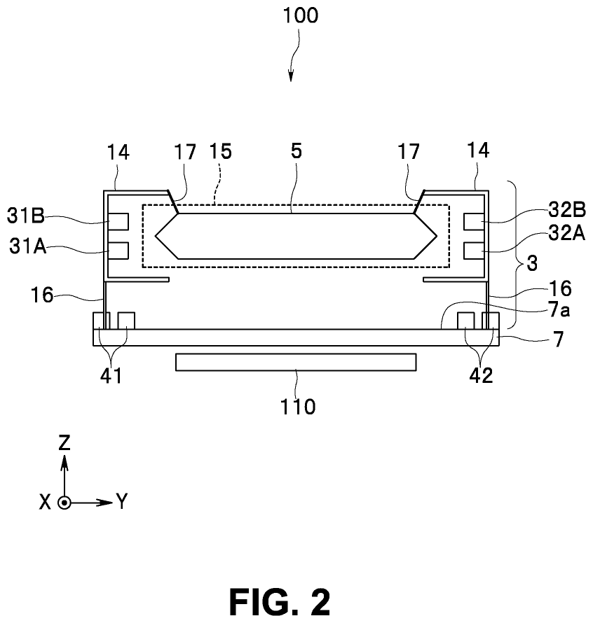

First, with reference to FIG. 1 and FIG. 2, a configuration of a camera module 100 including a magnetic sensor system according to a first example embodiment of the disclosure is described. FIG. 1 is a perspective view of the camera module 100. FIG. 2 is a schematic explanatory view illustrating an internal of the camera module 100. Note that, for ease of understanding, in FIG. 2, each part of the camera module 100 is drawn on a different scale and in a different layout than that in FIG. 1. The camera module 100 according to the example embodiment constitutes, for example, a portion of a camera for a smartphone having an optical image stabilization mechanism and an autofocus mechanism, and is used in combination with an image sensor 110 that uses CMOS or other similar techniques.

The camera module 100 of the example embodiment includes a driving device 3, a lens 5, a housing 6, and a substrate 7. The driving device 3 varies a relative position of the lens 5 with respect to an image sensor 110. In the example embodiment, in particular, the driving device 3 is configured to move the lens 5. The housing 6 protects the driving device 3. The substrate 7 includes a top surface 7a. Note that FIG. 1 omits the illustration of the substrate 7, and FIG. 2 omits the illustration of the housing 6.

The driving device 3 includes the magnetic sensor system according to the example embodiment. A position detection device according to the example embodiment is configured by the magnetic sensor system and a target object whose position is variable. In the example embodiment, the target object is the lens 5. The magnetic sensor system and the position detection device are described later.

Now, an X direction, a Y direction, and a Z direction are defined as shown in FIGS. 1 and 2. The X direction, the Y direction, and the Z direction are orthogonal to one another. In the example embodiment, the Z direction is a direction perpendicular to the top surface 7a of the substrate 7 (in FIG. 2, an upward direction). The X direction and the Y direction are both parallel to the top surface 7a of the substrate 7. The opposite directions to the X, Y, and Z directions will be expressed as −X, −Y, and −Z directions, respectively.

As used herein, the term “above” refers to positions arranged forward of a reference position in the Z direction, and “below” refers to positions arranged on a side of the reference position opposite from “above”. The expression “as viewed in a specific direction (for example, the Z direction)” indicates that the target object is viewed from a position away in the specific direction or in one direction parallel to the specific direction. With regard to the constituent elements of the camera module 100, a shape as viewed in the Z direction is referred to as a “planar shape”.

The lens 5 is arranged above the top surface 7a of the substrate 7 in such an orientation that the direction of its optical axis is parallel to the Z direction. The substrate 7 includes an opening portion (omitted in illustration) for allowing light passing through the lens 5 to pass. As illustrated in FIG. 2, the camera module 100 is in alignment with the image sensor 110 so that light passing through the lens 5 and the opening portion (omitted in illustration) enters the image sensor 110.

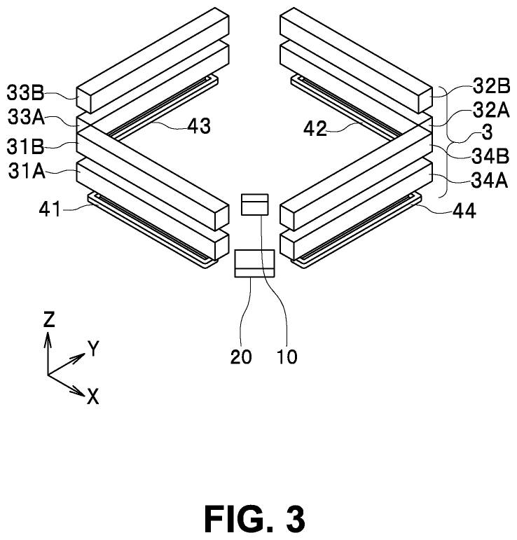

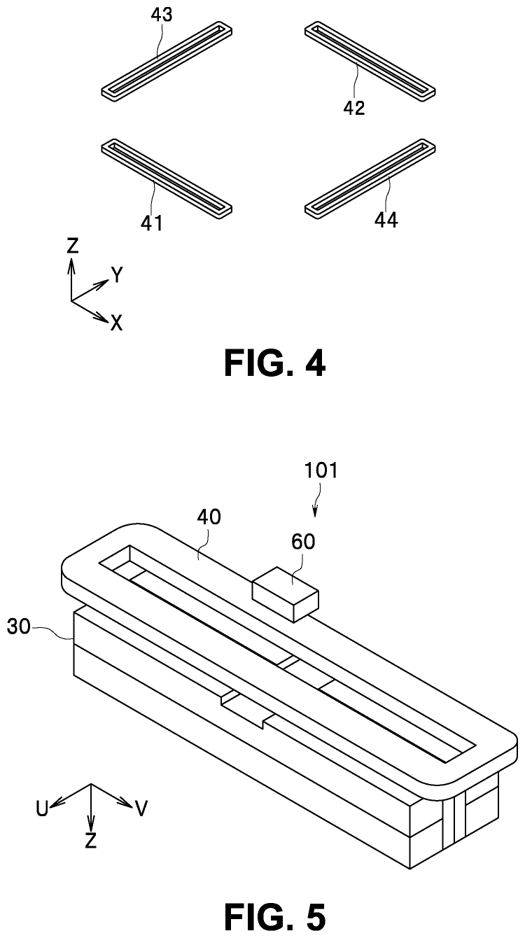

Next, with reference to FIG. 2, FIG. 3, and FIG. 4, the driving device 3 is described in detail. FIG. 3 is a perspective view illustrating the driving device 3. FIG. 4 is a perspective view illustrating a plurality of coils of the driving device 3.

The driving device 3 includes a first holding member 14, a second holding member 15, a plurality of first wires 16, and a plurality of second wires 17. The second holding member 15 holds the lens 5. Although omitted in illustration, the second holding member 15 has, for example, a cylindrical shape configured so that the lens 5 can be mounted therein.

The second holding member 15 is provided so that its position is variable in one direction, specifically, in the optical axis of the lens 5, in other words, in a direction parallel to the Z direction with respect to the first holding member 14. In the example embodiment, the first holding member 14 has a box-like shape configured so that the lens 5 and the second holding member 15 can be accommodated therein. The plurality of second wires 17 connect the first and second holding members 14 and 15, and support the second holding member 15 so that the second holding member 15 is movable in a direction parallel to the Z direction with respect to the first holding member 14.

The first holding member 14 is provided above the top surface 7a of the substrate 7 so that its position is variable with respect to the substrate 7 in a direction parallel to the X direction and in a direction parallel to the Y direction. The plurality of first wires 16 connect the substrate 7 and the first holding member 14, and support the first holding member 14 so that the first holding member 14 is movable with respect to the substrate 7 in a direction parallel to the X direction and in a direction parallel to the Y direction. When the relative position of the first holding member 14 with respect to the substrate 7 varies, the relative position of the second holding member 15 with respect to the substrate 7 also varies.

The driving device 3 further includes magnets 31A, 31B, 32A, 32B, 33A, 33B, 34A, and 34B, and coils 41, 42, 43, and 44. The magnet 31A is arranged forward of the lens 5 in the −Y direction. The magnet 32A is arranged forward of the lens 5 in the Y direction. The magnet 33A is arranged forward of the lens 5 in the −X direction. The magnet 34A is arranged forward of the lens 5 in the X direction. The magnets 31B, 32B, 33B and 34B are arranged above the magnets 31A, 32A, 33A and 34A, respectively. The magnets 31A, 31B, 32A, 32B, 33A, 33B, 34A, and 34B are fixed to the first holding member 14.

As illustrated in FIG. 3, the magnets 31A, 31B, 32A, and 32B each has a rectangular shape elongated in the X direction. The magnets 33A, 33B, 34A, and 34B each has a rectangular shape elongated in the Y direction. The magnets 31A and 32B are each configured to generate a magnetic field in the Y direction from the end surface in the Y direction. The magnets 31B and 32A are each configured to generate a magnetic field in the −Y direction from the end surface in the −Y direction. The magnets 33A and 34B are each configured to generate a magnetic field in the X direction from the end surface in the X direction. The magnets 33B and 34A are each configured to generate a magnetic field in the −X direction from the end surface in the −X direction.

The coil 41 is arranged between the magnet 31A and the substrate 7. The coil 42 is arranged between the magnet 32A and the substrate 7. The coil 43 is arranged between the magnet 33A and the substrate 7. The coil 44 is arranged between the magnet 34A and the substrate 7. The coils 41, 42, 43 and 44 are fixed to the substrate 7.

The driving device 3 further includes other two coils (omitted in illustration). For example, one of the other two coils is arranged between the magnets 31A and 31B, and the lens 5, and the other is arranged between the magnets 32A and 32B, and the lens 5. The other two coils (omitted in illustration) are fixed to the second holding member 15.

The coil 41 is subjected mainly to a magnetic field generated by the magnet 31A. The coil 42 is subjected mainly to a magnetic field generated by the magnet 32A. The coil 43 is subjected mainly to a magnetic field generated by the magnet 33A. The coil 44 is subjected mainly to a magnetic field generated by the magnet 34A.

The driving device 3 further includes a magnetic sensor 60 that is arranged in the vicinity of one of the coils 41 and 42 and fixed to the substrate 7, and a magnetic sensor 60 that is arranged in the vicinity of one of the coils 43 and 44 and fixed to the substrate 7. Herein, it is assumed that the two magnetic sensors 60 are arranged in the vicinities of the coils 41 and 44, respectively. As described later, the two magnetic sensors 60 are used to vary the position of the lens 5 so as to reduce the effect of hand-induced camera shake.

The magnetic sensor 60 arranged in the vicinity of the coil 41 detects the magnetic field generated by the magnet 31A, and generates a signal value corresponding to the position of the magnet 31A. The magnetic sensor 60 arranged in the vicinity of the coil 44 detects the magnetic field generated by the magnet 34A, and generates a signal value corresponding to the position of the magnet 34A. A configuration of the magnetic sensor 60 is described later.

The driving device 3 further includes a magnet 10 and a magnetic sensor 20. The magnetic sensor 20 is used to detect a position of the lens 5 when automatic focusing is performed. The magnetic sensor 20 is fixed to the substrate 7 in the vicinity of the end portion of the magnet 31A in the X direction and the end portion of the magnet 34A in the −Y direction. The magnetic sensor 20 is configured by, for example, an element that detects a magnetic field, such as a Hall element and a magnetoresistive effect element.

The magnet 10 is fixed to the second holding member 15 above the magnetic sensor 20. When the position of the second holding member 15 with respect to the first holding member 14 varies in a direction parallel to the Z direction, the position of the magnet 10 with respect to the first holding member 14 also varies in the direction parallel to the Z direction.

With reference to FIG. 2 to FIG. 4, an operation of the driving device 3 is described. First, an optical image stabilization mechanism and an autofocus mechanism are briefly described. The driving device 3 forms a part of the optical image stabilization mechanism and the autofocus mechanism. The driving device 3, the optical image stabilization mechanism and the autofocus mechanism are controlled by a control unit (omitted in illustration) outside the camera module 100.

The optical image stabilization mechanism is configured to detect hand-induced camera shake by using, for example, an acceleration sensor or a gyrosensor outside the camera module 100. Upon detection of hand-induced camera shake by the optical image stabilization mechanism, the control unit (omitted in illustration) controls the driving device 3 so as to vary the position of the lens 5 with respect to the substrate 7 depending on the mode of the camera shake. This stabilizes the absolute position of the lens 5 to reduce the effect of the camera shake. Note that the position of the lens 5 with respect to the substrate 7 varies in a direction parallel to the X direction or in a direction parallel to the Y direction, depending on the mode of the camera shake.

The autofocus mechanism is configured to detect a state in which focus is achieved on the subject, by using, for example, an image sensor 110 or an autofocus sensor. The control unit (omitted in illustration) varies the position of the lens 5 with respect to the substrate 7 in a direction parallel to the Z direction by the driving device 3 so as to achieve focus on the subject. This enables automatic focusing on the subject.

Next, the operation of the driving device 3 relating to the optical image stabilization mechanism is described. When a current flows through the coils 41 and 42 by the control unit (omitted in illustration), the first holding member 14 to which the magnets 31A and 32A are fixed moves in a direction parallel to the Y direction due to interaction between the magnetic fields generated by the magnets 31A and 32A and the magnetic fields generated by the coils 41 and 42. As a result, the lens 5 also moves in a direction parallel to the Y direction. When a current flows through the coils 43 and 44 by the control unit (omitted in illustration), the first holding member 14 to which the magnets 33A and 34A are fixed moves in a direction parallel to the X direction due to interaction between the magnetic fields generated by the magnets 33A and 34A and the magnetic fields generated by the coils 43 and 44. As a result, the lens 5 also moves in a direction parallel to the X direction. The control unit (omitted in illustration) detects the position of the lens 5 by measuring signals corresponding to the positions of the magnets 31A and 34A, which are generated by the two magnetic sensors 60.

Next, the operation of the driving device 3 relating to the autofocus mechanism is described. When the relative position of the lens 5 with respect to the substrate 7 is moved in the Z direction, the control unit (omitted in illustration) causes a Lorentz force in the Z direction to act on the other two coils (omitted in illustration) by the currents flowing through the respective other two coils (omitted in illustration) and the magnetic fields generated by magnets 31A, 31B, 32A, and 32B. With this, the second holding member 15 to which the other two coils (omitted in illustration) are fixed moves in the Z direction. As a result, the lens 5 also moves in the Z direction.

When the position of the lens 5 with respect to the substrate 7 is moved in the −Z direction, the control unit (omitted in illustration) causes a current to flow through the other two coils in a direction opposite to that in a case of moving the position of the lens 5 with respect to the substrate 7 in the Z direction.

When the relative position of the lens 5 with respect to the substrate 7 varies in a direction parallel to the Z direction, the relative position of the magnet 10 with respect to the magnetic sensor 20 also varies in a direction parallel to the Z direction. The magnetic sensor 20 detects at least a magnetic field generated by the magnet 10, and generates a signal corresponding to the position of the magnet 10.

The magnetic sensor 20 may detect a synthetic magnetic field of a magnetic field generated by the magnet 10, a magnetic field generated by the magnet 31A, and a magnetic field generated by the magnet 34A. A direction of the synthetic magnetic field may vary within a plane parallel to the top surface 7a of the substrate 7. At least one of a direction and a magnitude of the synthetic magnetic field varies depending on the relative position of the lens 5 with respect to the substrate 7.

Next, a schematic configuration of the magnetic sensor system according to the example embodiment is described. A magnetic sensor system 101 according to the example embodiment includes a magnetic field generating body configured to generate a target magnetic field, and a magnetic sensor configured to detect the target magnetic field at a detection position. In the example embodiment, the magnetic sensor 60 arranged in the vicinity of the coil 41 or the magnetic sensor 60 arranged in the vicinity of the coil 44 corresponds to the magnetic sensor of the example embodiment. In the magnetic sensor system including the magnetic sensor 60 arranged in the vicinity of the coil 41, the magnet 31A corresponds to the magnetic field generating body of the example embodiment. In the magnetic sensor system including the magnetic sensor 60 arranged in the vicinity of the coil 44, the magnet 34A corresponds to the magnetic field generating body of the example embodiment.

The magnetic sensor system 101 may further include a coil configured to vary the relative position of the magnetic field generating body with respect to the magnetic sensor 60. In the example embodiment, each of the coils 41 and 44 corresponds to the coil described above. In the following description, the magnetic field generating body forming the magnetic sensor system 101 is denoted by the reference numeral 30, and the coil forming the magnetic sensor system 101 is denoted by the reference numeral 40.

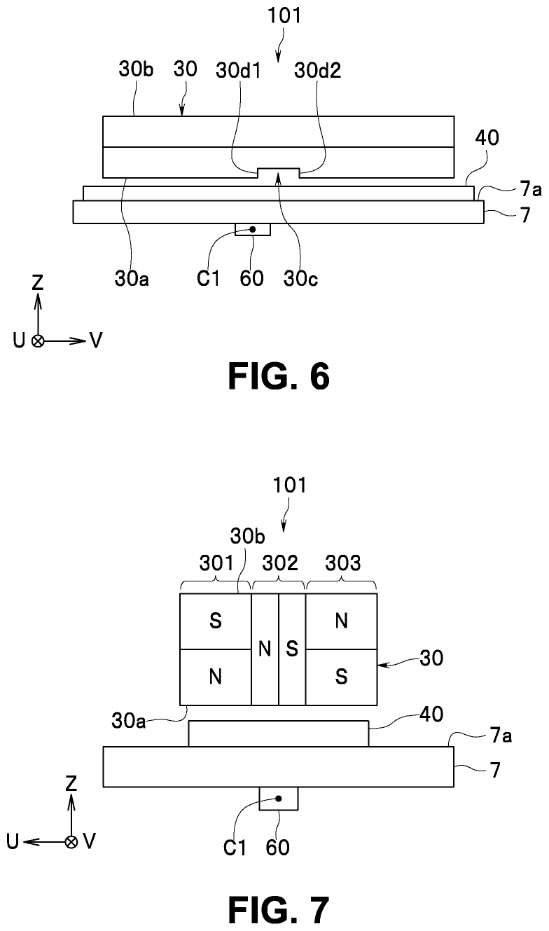

Next, with reference to FIG. 5, FIG. 6, and FIG. 7, the magnetic sensor system 101 including the magnetic field generating body 30, the magnetic sensor 60, and the coil 40 is described. FIG. 5 is a perspective view illustrating the magnetic sensor system 101. FIG. 6 and FIG. 7 are side views each illustrating the magnetic sensor system 101.

Here, as illustrated in FIG. 5 to FIG. 7, a U direction and a V direction that intersect with the Z direction and intersect with each other are defined. The U direction, the V direction, and the Z direction may be orthogonal to one another. A direction opposite to the U direction is a −U direction, and a direction opposite to the V direction is a −V direction.

When the magnetic field generating body 30 and the coil 40, which are illustrated in FIG. 5 and FIG. 7, correspond to the magnet 31A and the coil 41, which are illustrated in FIG. 3, respectively, the U direction corresponds to the Y direction, and the V direction corresponds to the X direction. When the magnetic field generating body 30 and the coil 40, which are illustrated in FIG. 5 and FIG. 7, correspond to the magnet 34A and the coil 44, which are illustrated in FIG. 3, respectively, the U direction corresponds to the −X direction and the V direction corresponds to the Y direction.

The target magnetic field at the detection position includes a first component H1, which is a component in a direction parallel to the Z direction, a second component H2, which is a component in a direction parallel to the U direction, and a third component H3, which is a component in a direction parallel to the V direction. The Z direction corresponds to the “first direction” in the disclosure. The U direction or a direction parallel to the U direction corresponds to the “second direction” in the disclosure. The V direction or a direction parallel to the V direction corresponds to the “third direction” in the disclosure.

The magnetic field generating body 30 and the magnetic sensor 60 are arrayed in the Z direction. For example, the detection position may be a position at which the magnetic sensor 60 is arranged. As viewed in the Z direction, the detection position, in other words, the position at which the magnetic sensor 60 is arranged is a position overlapping with the magnetic field generating body 30, and is a position away from both ends of the magnetic field generating body 30 in a direction parallel to the V direction.

The magnetic sensor 60 may be arranged to overlap with a region surrounded by the coil 40 as viewed in the Z direction. The magnetic sensor 60 may be arranged to overlap with the coil 40, or may be arranged not to overlap with the coil 40 as viewed in a direction orthogonal to the Z direction (for example, the U direction). When the magnetic sensor 60 is arranged to overlap with the coil 40 as viewed in a direction orthogonal to the Z direction, the magnetic sensor 60 is arranged on the inner side of the coil 40.

The magnetic field generating body 30 and the magnetic sensor 60 are configured so that the relative position of the magnetic field generating body 30 with respect to the magnetic sensor 60 varies in a direction parallel to the U direction. As described above, the magnetic sensor 60 is fixed to the substrate 7, and the magnet 31A and the magnet 34A, in other words, the magnetic field generating bodies 30 are fixed to the first holding member 14 (see FIG. 2). When the position of the first holding member 14 with respect to the substrate 7 varies in a direction parallel to the U direction, the relative position of the magnetic field generating body 30 with respect to the magnetic sensor 60 also varies in a direction parallel to the U direction. The detection value of the magnetic sensor 60 corresponds to the relative position of the magnetic field generating body 30 with respect to the magnetic sensor 60 in a direction parallel to the U direction. Hereinafter, the relative position of the magnetic field generating body 30 with respect to the magnetic sensor 60 in a direction parallel to the U direction is simply referred to as a relative position.

The magnetic field generating body 30 and the magnetic sensor 60 are configured so that the first to third components H1 to H3 vary when the relative position varies. The magnetic sensor 60 includes a plurality of magnetoresistive elements each having sensitivity in a direction intersecting with the Z direction. Hereinafter, the magnetoresistive element is referred to as an MR element. The plurality of MR elements form a detection circuit so that the magnetic sensor 60 has sensitivity in a direction intersecting with the Z direction. In the example embodiment, in particular, the magnetic sensor 60 has sensitivity in the V direction, but does not have sensitivity in the Z direction.

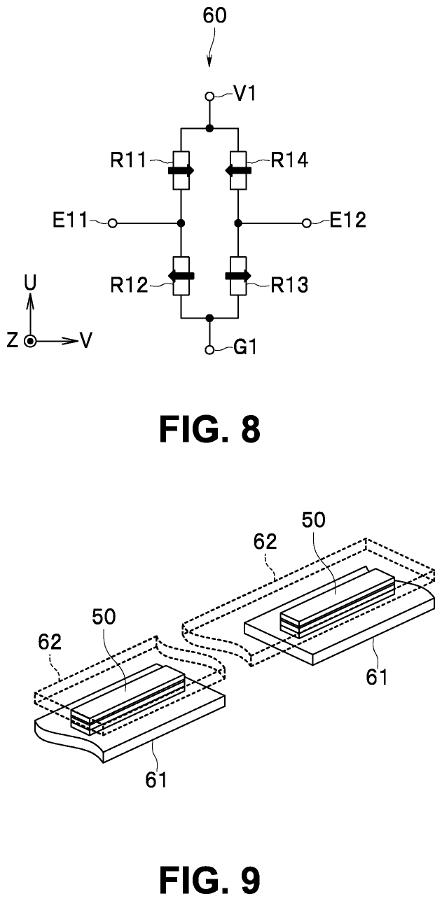

Next, with reference to FIG. 8, an example of a circuit configuration of the magnetic sensor 60 is described. FIG. 8 is a circuit diagram illustrating a circuit configuration of the magnetic sensor 60. The magnetic sensor 60 includes a power supply port V1 to which a voltage or a current is applied, a ground port G1 that is connected to the ground, a first output port E11, a second output port E12, and four resistor sections R11, R12, R13, and R14. The resistor section R11 is provided between the power supply port V1 and the first output port E11. The resistor section R12 is provided between the first output port E11 and the ground port G1. The resistor section R13 is provided between the second output port E12 and the ground port G1. The resistor section R14 is provided between the power supply port V1 and the second output port E12.

Each of the resistor sections R11 to R14 includes at least one MR element 50. Each of the resistor sections R11 to R14 may include a plurality of MR elements 50 connected in series. Now, with reference to FIG. 9, an example of a configuration of the resistor sections R11 to R14 is described. FIG. 9 is a perspective view illustrating a part of one resistor section among the resistor sections R11 to R14. In this example, one resistor section includes a plurality of lower electrodes 61, a plurality of MR elements 50, and a plurality of upper electrodes 62. The plurality of lower electrodes 61 are arranged on a substrate (omitted in illustration). Each of the lower electrodes 61 has an elongated shape. A gap is formed between two lower electrodes 61 that are adjacent to each other in the longitudinal direction of the lower electrodes 61. The MR elements 50 are arranged on the top surface of the lower electrode 61, near opposite ends of the lower electrode 61 in the longitudinal direction. Each of the upper electrode 62 connects the two adjacent MR elements 50 that are arranged on the two lower electrodes 61 adjacent in the longitudinal direction of the lower electrodes 61. With this configuration, the plurality of MR elements 50 are connected in series by the plurality of lower electrodes 61 and the plurality of upper electrodes 62.

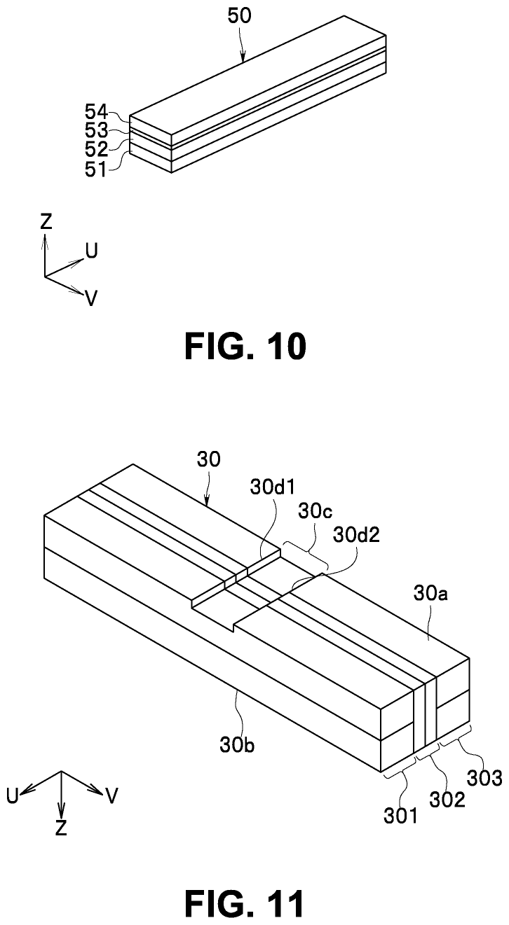

Each of the plurality of MR elements 50 may be a spin-valve MR element. FIG. 10 is a perspective view illustrating the MR element 50. The MR element 50 includes a magnetization pinned layer 52 in which a magnetization direction is fixed, a free layer 54 in which a magnetization direction is variable in accordance with the target magnetic field, and a gap layer 53 that is arranged between the magnetization pinned layer 52 and the free layer 54. The MR element 50 may be a tunneling magnetoresistive (TMR) element or a giant magnetoresistive (GMR) element. In the TMR element, the gap layer is a tunnel barrier layer. In the GMR element, the gap layer is a nonmagnetic conductive layer. The resistance value of the MR element 50 varies in accordance with the angle that the magnetization direction of the free layer 54 forms with respect to the magnetization direction of the magnetization pinned layer 52. The resistance value of the MR element 50 is at its minimum value when the foregoing angle is 0 degrees, and at its maximum value when the foregoing angle is 180 degrees. In FIG. 8, the solid arrow indicates the magnetization direction of the magnetization pinned layer 52.

The MR element 50 further includes an antiferromagnetic layer 51. The antiferromagnetic layer 51, the magnetization pinned layer 52, the gap layer 53, and the free layer 54 are stacked in the stated order. The antiferromagnetic layer 51 is formed of an antiferromagnetic material. The antiferromagnetic layer 51 is in exchange coupling with the magnetization pinned layer 52 so as to fix the magnetization direction of the magnetization pinned layer 52. Note that the magnetization pinned layer 52 may be a so-called self-pinned layer (Synthetic Ferri Pinned layer, SFP layer). The self-pinned layer has a stacked ferri structure in which a ferromagnetic layer, a nonmagnetic intermediate layer, and a ferromagnetic layer are stacked, and the two ferromagnetic layers are antiferromagnetically coupled. When the magnetization pinned layer 52 is a self-pinned layer, the antiferromagnetic layer 51 may be omitted.

Note that the layers 51 to 54 of each of the MR elements 50 may be stacked in the reverse order to that illustrated in FIG. 10.

The MR element 50 has sensitivity in a direction intersecting with the Z direction, but does not have sensitivity in the Z direction. In other words, the magnetization direction of the magnetization pinned layer 52 is a direction intersecting with the Z direction, and the magnetization direction of the free layer 54 varies in a direction intersecting with the Z direction. In the example illustrated in FIG. 8, the magnetization direction of the magnetization pinned layer 52 in each of the plurality of MR elements 50 of the resistor sections R11 and R13 is the V direction. The magnetization direction of the magnetization pinned layer 52 in each of the plurality of MR elements 50 of the resistor sections R12 and R14 is the −V direction.

Note that, in the light of the production accuracy of the MR elements 50 and other factors, the magnetization directions of the magnetization pinned layers 52 of the plurality of MR elements 50 in the resistor sections R11 to R14 may be slightly different from the above-described directions.

The free layer 54 may have shape anisotropy so that an easily magnetized axis direction is a direction parallel to the U direction. When the direction of the third component H3 of the target magnetic field is the V direction, the magnetization direction of the free layer 54 is inclined from a direction parallel to the U direction to the V direction. As a result, the resistance value of each of the plurality of MR elements 50 of the resistor sections R11 and R13 is reduced, and the resistance value of each of the plurality of MR elements 50 of the resistor sections R12 and R14 is increased. When the direction of the third component H3 of the target magnetic field is the −V direction, the magnetization direction of the free layer 54 is inclined from a direction parallel to the U direction to the −V direction. As a result, the resistance value of each of the plurality of MR elements 50 of the resistor sections R11 and R13 is increased, the resistance value of each of the plurality of MR elements 50 of the resistor sections R12 and R14 is reduced.

As the third component H3 of the target magnetic field is increased, the resistance value of the MR element 50 varies so that an increase amount or a reduction amount thereof is increased. As the third component H3 of the target magnetic field is reduced, the resistance value of the MR element 50 varies so that an increase amount or a reduction amount thereof is reduced.

As described above, the MR element 50 has sensitivity in a direction parallel to the V direction. The potential of the first output port E11 and the potential of the second output port E12 vary in accordance with the third component H3 of the target magnetic field. The magnetic sensor 60 may generate a signal corresponding to the potential of the first output port E11 and a signal corresponding to the potential of the second output port E12, as detection signals. Alternatively, the magnetic sensor 60 may generate a signal corresponding to a potential difference between the first output port E11 and the second output port E12, as a detection signal. In such a case, the magnetic sensor 60 may further include a differential amplifier (differential detector) that outputs the signal corresponding to the potential difference between the first output port E11 and the second output port E12, as the detection signal. The detection signal has a correspondence with the third component H3 of the target magnetic field. The magnetic sensor 60 has sensitivity in a direction parallel to the V direction.

Next, with reference to FIG. 5 to FIG. 7 and FIG. 11, the magnetic field generating body 30 is further described in detail. FIG. 11 is a perspective view of the magnetic field generating body 30. The magnetic field generating body 30 may include a first surface 30a facing the magnetic sensor 60 and a second surface 30b on a side opposite to the first surface 30a. The first surface 30a is located at the end of the magnetic field generating body 30 in the −Z direction. The second surface 30b is located at the end of the magnetic field generating body 30 in the Z direction.

The first surface 30a may include a step-like portion 30c including at least one step. In the example embodiment, the step-like portion 30c may include a recessed surface that is recessed from the first surface 30a to the second surface 30b. In the example illustrated in FIG. 11, the recessed surface includes a flat surface that is a planar surface parallel to the first surface 30a and is located between the first surface 30a and the second surface 30b in a direction parallel to the Z direction, and two step surfaces that connect the first surface 30a and the flat surface to each other. Each of the two step surfaces forms a step between the first surface 30a and the flat surface. Therefore, the step-like portion 30c includes two steps. In FIG. 11, the reference numeral 30d1 denotes a step located at the end of the step-like portion 30c on the −V direction side, and the reference numeral 30d2 denotes a step located at the end of the step-like portion 30c on the V direction side. Note that the recessed surface may include at least one curved surface in place of the flat surface or in addition to the flat surface.

The width of the step-like portion 30c, which is a dimension of the step-like portion 30c in a direction parallel to the V direction, is constant or substantially constant regardless a position in a direction parallel to the U direction.

At least a part of the magnetic sensor 60 may overlap with the step-like portion 30c as viewed in the Z direction. In FIG. 6 and FIG. 7, the symbol C1 denotes a gravity center of the magnetic sensor 60. The gravity center C1 of the magnetic sensor 60 may match with the gravity center of the planar shape of the magnetic sensor 60 as viewed in the Z direction. The magnetic sensor 60 may be arranged so that the gravity center C1 of the magnetic sensor 60 does not overlap with the center of the step-like portion 30c in a direction parallel to the V direction as viewed in the Z direction. The magnetic sensor 60 may be arranged so as to overlap with one of the step 30d1 and the step 30d2 as viewed in the Z direction. In the example illustrated in FIG. 6, the magnetic sensor 60 overlaps with the step 30d1 as viewed in the Z direction.

The magnetic field generating body 30 may include a magnet including a plurality of portions each including an N pole and an S pole. In the example illustrated in FIG. 7 and FIG. 11, the magnetic field generating body 30 includes a magnet including a first portion 301, a second portion 302, and a third portion 303 each including an N pole and an S pole. The first portion 301, the second portion 302, and the third portion 303 may be arrayed in the stated order along the −U direction.

FIG. 7 illustrates an example of arrangement of the N pole and the S pole of each of the first to third portions 301, 302, and 303. In the example illustrated in FIG. 7, the direction in which the N pole and the S pole are arrayed in the first portion 301 and the direction in which the N pole and the S pole are arrayed in the second portion 302 are different from each other. The direction in which the N pole and the S pole are arrayed in the second portion 302 and the direction in which the N pole and the S pole are arrayed in the third portion 303 are different from each other. In the first portion 301, the N pole and the S pole are arrayed in the stated order in the Z direction. In the second portion 302, the N pole and the S pole are arrayed in the stated order in the −U direction. In the third portion 303, the N pole and the S pole are arrayed in the stated order in the −Z direction.

In the example illustrated in FIG. 7, at the first surface 30a of the magnetic field generating body 30, the N pole of the first portion 301, the N pole and the S pole of the second portion 302, and the S pole of the third portion 303 appear. At the first surface 30a, the N pole of the first portion 301 is adjacent to the N pole of the second portion 302, and the S pole of the third portion 303 is adjacent to the S pole of the second portion 302.

In the example illustrated in FIG. 7, at the second surface 30b of the magnetic field generating body 30, the S pole of the first portion 301, the N pole and the S pole of the second portion 302, and the N pole of the third portion 303 appear. At the second surface 30b, the S pole of the first portion 301 is adjacent to the N pole of the second portion 302, and the N pole of the third portion 303 is adjacent to the S pole of the second portion 302.

The step-like portion 30c is formed at each of the first to third portions 301, 302, and 303. The width of the step-like portion 30c at each of the first to third portions 301, 302, and 303 is constant or substantially constant. The step-like portion 30c of the first portion 301, the step-like portion 30c of the second portion 302, and the step-like portion 30c of the third portion 303 may be continuous with each other.

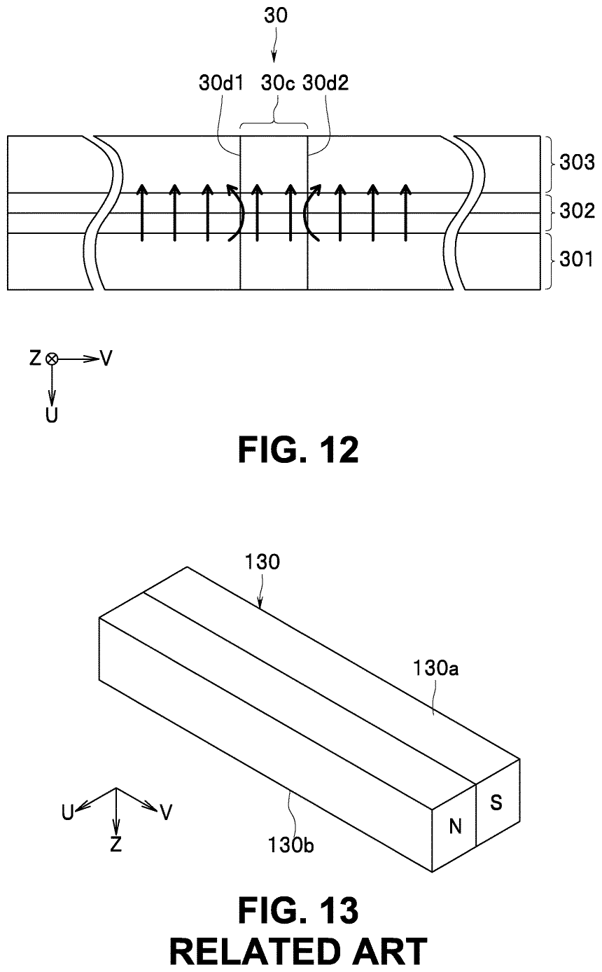

Next, with reference to FIG. 12, the direction of the target magnetic field generated by the magnetic field generating body 30 is described. FIG. 12 is a plan view of the magnetic field generating body 30. In FIG. 12, the magnetic field generated by the magnetic field generating body 30 is indicated by using a plurality of arrows. The direction of the arrow indicates a direction of a magnetic field in a virtual plane that faces the first surface 30a of the magnetic field generating body 30 and is orthogonal to the Z direction. The magnetic sensor 60 and the magnetic field generating body 30 are configured so that the target magnetic field, which is a part of the magnetic field generated by the magnetic field generating body 30, is applied to the magnetic sensor 60. The target magnetic field includes the first component H1, which is a component in a direction parallel to the Z direction, the second component H2, which is a component in a direction parallel to the U direction, and the third component H3, which is a component in a direction parallel to the V direction. Each of the plurality of arrows illustrated in FIG. 12 indicates the direction of the second component H2 or the direction of the component obtained by synthesizing the second component H2 and the third component H3.

Here, a figure formed by projecting each of the two steps 30d1 and 30d2 of the step-like portion 30c onto the above-mentioned virtual plane is referred to as a projection figure. The third component H3 in the virtual plane is generated at a position overlapping with the projection figure of each of the steps 30d1 and 30d2 or in the vicinity of the position. At the position overlapping with the projection figure of the step 30d1 or in the vicinity of the position, the magnitude of the third component H3 is 0 at the center or in the vicinity of the center of the projection figure of the step 30d1 in a direction parallel to the U direction, and is increased as being away from the center. The direction of the third component H3 on the U direction of the above-mentioned center is the V direction, and the direction of the third component H3 on the −U direction of the above-mentioned center is the −V direction. Hereinafter, the center of the projection figure of the step 30d1 in a direction parallel to the U direction is simply referred to as the center of the projection figure of the step 30d1.

At the position overlapping with the projection figure of the step 30d2 or in the vicinity of the position, the magnitude of the third component H3 is 0 at the center or in the vicinity of the center of the projection figure of the step 30d2 in a direction parallel to the U direction, and is increased as being away from the center. The direction of the third component H3 on the U direction of the above-mentioned center is the −V direction, and the direction of the third component H3 on the −U direction of the above-mentioned center is the V direction. Hereinafter, the center of the projection figure of the step 30d2 in a direction parallel to the U direction is simply referred to as the center of the projection figure of the step 30d2.

Now, a case where the detection position exists in the above-mentioned virtual plane and the detection position overlaps with the projection figure of the step 30d1 is considered. The magnitude of the third component H3 at the detection position is 0 when the center of the projection figure of the step 30d1 matches with the detection position, and is increased as the center of the projection figure of the step 30d1 is away from the detection position. The relative position of the center of the projection figure of the step 30d1 with respect to the detection position has a correspondence with the relative position of the magnetic field generating body 30 with respect to the magnetic sensor 60. In other words, when the relative position of the magnetic field generating body 30 with respect to the magnetic sensor 60 varies, the relative position of the center of the projection figure of the step 30d1 with respect to the detection position varies. With this, the magnitude and the direction of the third component H3 vary. Therefore, the relative position of the magnetic field generating body 30 with respect to the magnetic sensor 60 can be detected by detecting the third component H3 by the magnetic sensor 60.

As described above, the detection signal generated by the magnetic sensor 60 has a correspondence with the third component H3 of the target magnetic field. Therefore, the detection signal generated by the magnetic sensor 60 has a correspondence with the relative position of the magnetic field generating body 30 with respect to the magnetic sensor 60. In the example embodiment, the detection signal itself generated by the magnetic sensor 60 may be regarded as the detection value of the magnetic sensor 60. Alternatively, a value obtained by converting the detection signal generated by the magnetic sensor 60 into the relative position of the magnetic field generating body 30 with respect to the magnetic sensor 60 may be regarded as the detection value of the magnetic sensor 60.

Next, the position detection device according to the example embodiment is described. The position detection device according to the example embodiment detects a position of the target object whose position is variable. In the example embodiment, in particular, the target object is the lens 5 (see FIG. 1 and FIG. 2). The position detection device includes the magnetic sensor system 101 according to the example embodiment and the target object (the lens 5). The relative position, which is the relative position of the magnetic field generating body 30 with respect to the magnetic sensor 60, has a correspondence with the position of the target object, in other words, the lens 5. In other words, when the lens 5 moves in a direction parallel to the X direction or a direction parallel to the Y direction, the magnets 31A and 34A fixed to the first holding member 14, in other words, the magnetic field generating body 30 also moves in a direction parallel to the X direction or a direction parallel to the Y direction. With this, the relative position varies in a direction parallel to the X direction or a direction parallel to the Y direction.

As described above, the detection signal generated by the magnetic sensor 60 has a correspondence with the relative position of the magnetic field generating body 30 with respect to the magnetic sensor 60. Therefore, the detection signal generated by the magnetic sensor 60 has a correspondence with the position of the lens 5.

Next, operations and effects of the magnetic sensor system 101 according to the example embodiment are described. In the example embodiment, the magnetic field generating body 30 is configured so that, at the detection position, the target magnetic field includes the third component H3, in other words, a component in a direction parallel to the V direction. In the example embodiment, the target magnetic field at the detection position further includes the first component H1, in other words a component in a direction parallel to the Z direction. For example, the relative position of the magnetic field generating body 30 with respect to the magnetic sensor 60 can be detected by detecting the first component H1. However, when the coil 41 or 44 that generates a magnetic field in a direction parallel to the Z direction exists in the vicinity of the magnetic sensor 60 as in the camera module 100, the magnetic field generated by the coil 41 or 44 is also applied to the magnetic sensor 60 in addition to the first component H1. Therefore, in such a case, it is difficult to detect the first component H1 without being affected by the magnetic field generated by the coil 41 or 44, which is a magnetic field other than the target magnetic field.

In contrast, in the example embodiment, the magnetic sensor 60 has sensitivity in a direction parallel to the V direction, and is capable of detecting the third component H3. In the example embodiment, in particular, the magnetic sensor 60 does not have sensitivity in a direction parallel to the Z direction. With this, according to the example embodiment, the third component H3 of the target magnetic field can be detected without being affected by a magnetic field other than the target magnetic field.

Next, the effects of the example embodiment are further described in detail in comparison with a magnetic field generating body in a comparative example. First, a magnetic field generating body 130 in the comparative example is described. FIG. 13 is a perspective view illustrating the magnetic field generating body 130 in the comparative example. The magnetic field generating body 130 in the comparative example is configured by a magnet including a pair of an N pole and an S pole. The N pole and the S pole are arrayed in a direction parallel to the U direction.

The magnetic field generating body 130 includes a first surface 130a and a second surface 130b on a side opposite to the first surface 130a. The first surface 130a is located at the end of the magnetic field generating body 130 in the −Z direction. The second surface 130b is located at the end of the magnetic field generating body 130 in the Z direction.

A step is not formed at the first surface 130a of the magnetic field generating body 130. The entire first surface 130a of the magnetic field generating body 130 is a surface parallel to or substantially parallel to the UV plane.

Next, description is made on results of a first simulation that examines a magnitude of the magnetic field generated by the magnetic field generating body 130, which is a magnetic field on the virtual plane that faces the first surface 130a of the magnetic field generating body 130 and is orthogonal to the Z direction. In the first simulation, a position on the virtual plane that matches with the gravity center of the planar shape of the magnetic field generating body 130 as viewed in the Z direction is set as a reference position. Further, magnitudes of magnetic fields at a plurality of positions on a virtual line that passes through the reference position and is parallel to the U direction are obtained. In the first simulation, as the magnitude of the magnetic field, a magnitude of the first component in a direction parallel to the Z direction, a magnitude of the second component in a direction parallel to the U direction, and a magnitude of the third component in a direction parallel to the V direction are obtained.

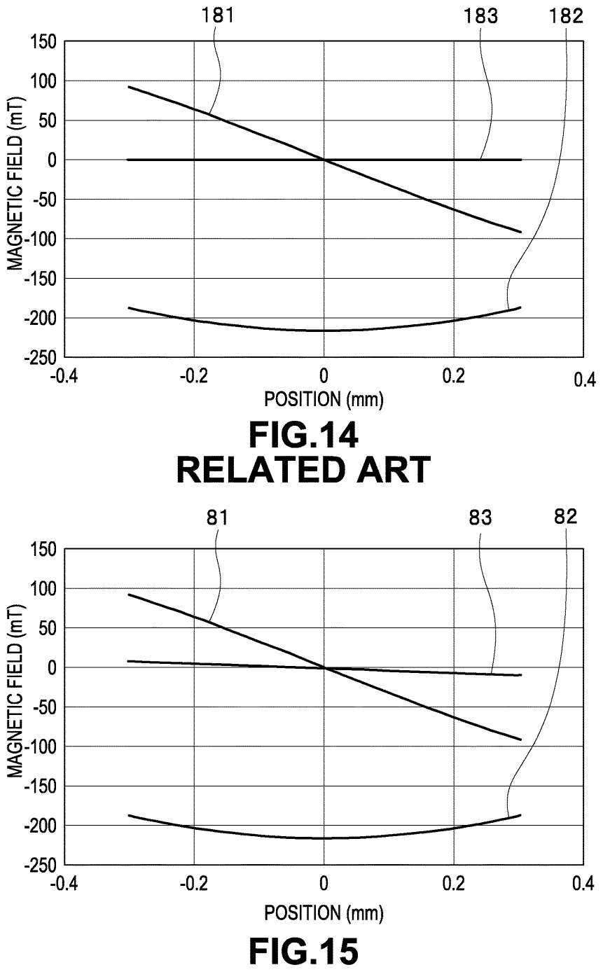

FIG. 14 is a characteristic chart showing results of the first simulation. In FIG. 14, the horizontal axis indicates positions on the above-mentioned virtual line, and the vertical axis indicates a magnitude of a magnetic field. Note that, in the horizontal axis of FIG. 14, the reference position is set to zero. In FIG. 14, the reference numeral 181 denotes the first component, the reference numeral 182 denotes the second component, and the reference numeral 183 denotes the third component. As illustrated in FIG. 14, in the comparative example, the magnitude of the component in the third direction is constant regardless of the position.

Next, description is made on results of a second simulation that examines a magnitude of the magnetic field generated by the magnetic field generating body 30 in the example embodiment, which is a magnetic field on the virtual plane that faces the first surface 30a of the magnetic field generating body 30 and is orthogonal to the Z direction. In the second simulation, the center of the projection figure of the step 30d1 in a direction parallel to the U direction is set as a reference position. Further, magnitudes of magnetic fields at a plurality of positions on a virtual line that passes through the reference position and is parallel to the U direction are obtained. In the second simulation, as the magnitude of the magnetic field, a magnitude of the first component H1, a magnitude of the second component H2, and a magnitude of the third component H3 are obtained.

FIG. 15 is a characteristic chart showing results of the second simulation. In FIG. 15, the horizontal axis indicates positions on the above-mentioned virtual line, and the vertical axis indicates a magnitude of a magnetic field. Note that, in the horizontal axis of FIG. 15, the reference position is set to zero. In FIG. 15, the reference numeral 81 denotes the first component H1, the reference numeral 82 denotes the second component H2, and the reference numeral 83 denotes the third component H3.

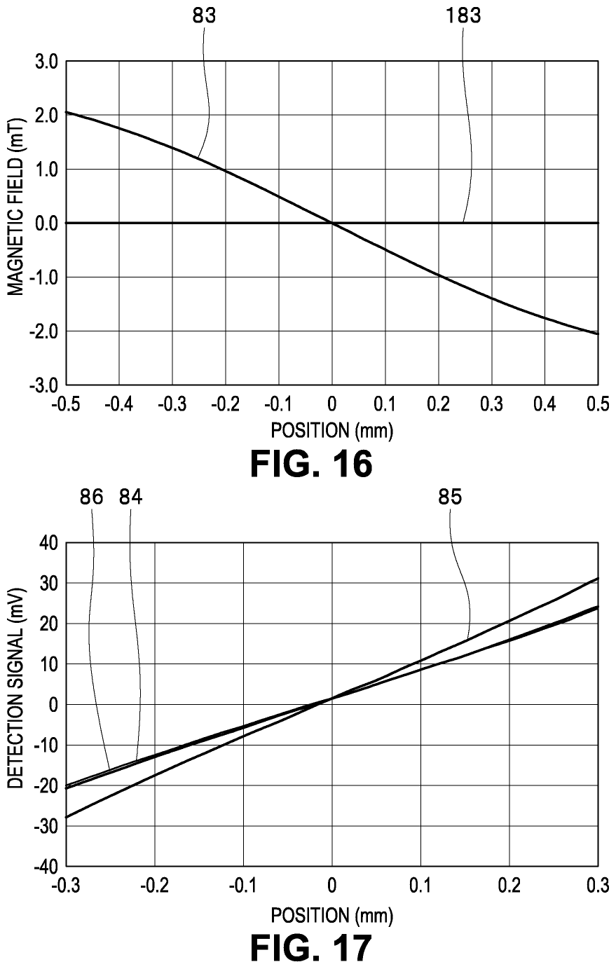

FIG. 16 is a characteristic chart showing the third component (the reference numeral 183) in the first simulation and the third component H3 (the reference numeral 83) in the second simulation. In FIG. 16, the horizontal axis indicates positions on the above-mentioned virtual line, and the vertical axis indicates a magnitude of a magnetic field. As illustrated in FIG. 15 and FIG. 16, the third component H3 (the reference numeral 83) varies in accordance with the position. As understood from the results of the first and second simulations, the relative position of the magnetic field generating body 30 with respect to the magnetic sensor 60 can be detected based on the third component H3 by using the magnetic field generating body 30 in the example embodiment.

Next, description is made on results of a third simulation that examines a detection signal when the magnetic sensor 60 is shifted in a direction parallel to the V direction. In the third simulation, a detection signal of the magnetic sensor 60 in a first case where the magnetic sensor 60 is arranged so that the reference position described in the second simulation is the detection position is obtained. In the third simulation, the signal corresponding to the potential difference between the first output port E11 and the second output port E12 is regarded as the detection signal. Further, the detection signal when the magnetic sensor 60 moves in a direction parallel to the U direction from the reference position is obtained. In the third simulation, similarly to the above-mentioned manner, a detection signal in a second case where the magnetic sensor 60 moves in the −V direction from the reference position by 0.3 mm and a detection signal in a third case where the magnetic sensor 60 moves in the V direction from the reference position by 0.3 mm are obtained.

In the third simulation, by using the detection signal, crosstalk is obtained based on Equation (1) given below. Note that, in Equation (1), Vc represents the crosstalk, V represents the detection signal of the magnetic sensor 60, V0 represents the detection signal of the magnetic sensor 60 when the magnetic sensor 60 is arranged so that the reference position is the detection position, and V1 represents the maximum value of the detection signal of the magnetic sensor 60 when the magnetic sensor 60 is arranged so that the reference position is the detection position.

$$Vc = ( V - V 0 ) / V 1 \qquad ( 1 )$$

FIG. 17 is a characteristic chart showing a detection signal obtained by the third simulation. In FIG. 17, the horizontal axis indicates a position of the magnetic sensor 60, and the vertical axis indicates a magnitude of a detection signal. In FIG. 17, the reference numeral 84 denotes the detection signal in the second case, the reference numeral 85 denotes the detection signal in the first case, and the reference numeral 86 denotes the detection signal in the third case. Note that, in FIG. 17, the detection signal in the second case (the reference numeral 84) and the detection signal in the third case (the reference numeral 86) substantially overlap with each other. It is understood from FIG. 17 that the variation amount of the detection signal in the first case where the position of the magnetic field generating body 30 is varied (the reference numeral 85), in other words, the sensitivity of the magnetic sensor 60 is higher than those in the second case and the third case.

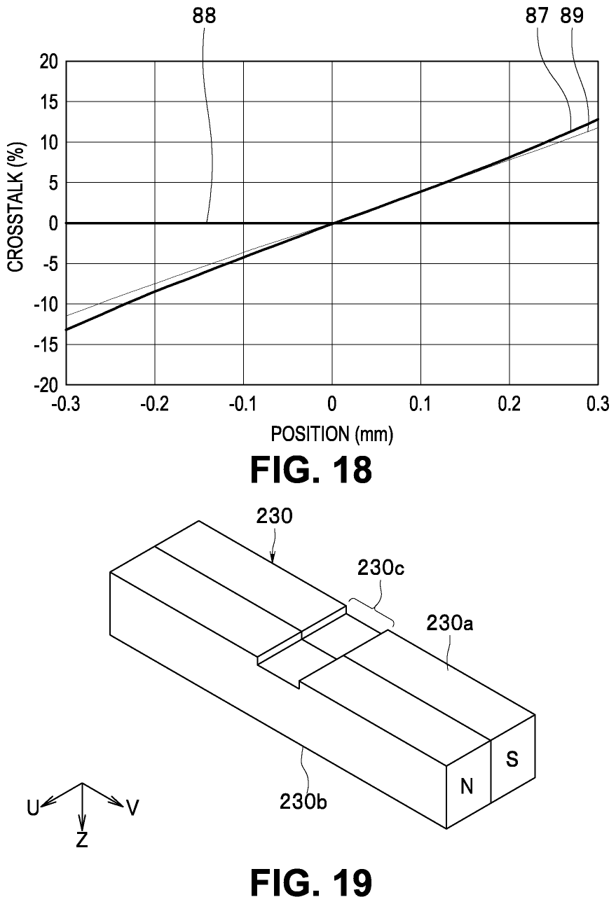

FIG. 18 is a characteristic chart showing crosstalk obtained by the third simulation. In FIG. 18, the horizontal axis indicates a position of the magnetic sensor 60, and the vertical axis indicates a magnitude of the crosstalk. In FIG. 18, the reference numeral 87 denotes crosstalk in the second case, the reference numeral 88 denotes crosstalk in the first case, and the reference numeral 89 denotes crosstalk in the third case. The crosstalk in the second case (the reference numeral 87) indicates a deviation amount of the detection signal in the second case (the reference numeral 84) from the detection signal in the first case (the reference numeral 85). The crosstalk in the third case (the reference numeral 89) indicates a deviation amount of the detection signal in the third case (the reference numeral 86) from the detection signal in the first case (the reference numeral 85). It is understood from FIG. 18 that the deviation amount is increased as being away from the reference position.

As understood from the results in the third simulation, by arranging the magnetic sensor 60 so that the projection figure of the step 30d1 and the detection position overlap with each other, the sensitivity of the magnetic sensor 60 can be higher.

### Modification Example

Next, first to seventh modification examples of the magnetic field generating body in the example embodiment are described. First, with reference to FIG. 19, a magnetic field generating body 230 in the first modification example is described. FIG. 19 is a perspective view illustrating the magnetic field generating body 230. The magnetic field generating body 230 may include a magnet including a pair of an N pole and an S pole. The N pole and the S pole may be arrayed in the −U direction. The magnetic field generating body 230 substantially includes only the second portion 302 of the magnetic field generating body 30 in the example embodiment.

The magnetic field generating body 230 includes a first surface 230a facing the magnetic sensor 60 and a second surface 230b on a side opposite to the first surface 230a. The first surface 230a includes a step-like portion 230c having a shape similar to that of the step-like portion 30c in the example embodiment.

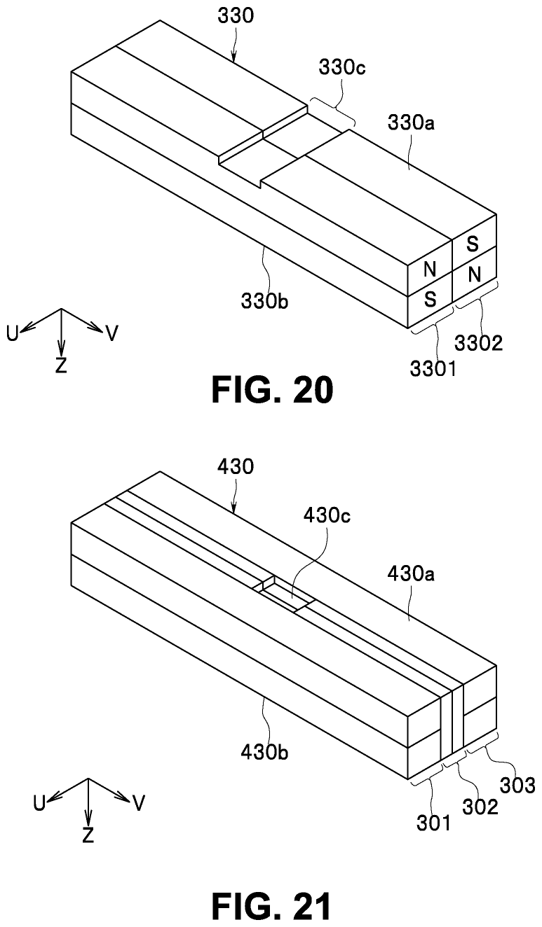

Next, with reference to FIG. 20, a magnetic field generating body 330 in the second modification example is described. FIG. 20 is a perspective view illustrating the magnetic field generating body 330. The magnetic field generating body 330 may include a first portion 3301 and a second portion 3302 each including an N pole and an S pole. The first portion 3301 and the second portion 3302 may be arrayed in the stated order in the −U direction. The first portion 3301 substantially corresponds to the first portion 301 of the magnetic field generating body 30 in the example embodiment. The second portion 3302 substantially corresponds to the third portion 303 of the magnetic field generating body 30 in the example embodiment.

The magnetic field generating body 330 includes a first surface 330a facing the magnetic sensor 60 and a second surface 330b on a side opposite to the first surface 330a. The first surface 330a includes a step-like portion 330c having a shape similar to that of the step-like portion 30c in the example embodiment. The step-like portion 330c is formed at each of the first and second portions 3301 and 3302.

Next, with reference to FIG. 21, a magnetic field generating body 430 in the third modification example is described. FIG. 21 is a perspective view illustrating the magnetic field generating body 430. The magnetic field generating body 430 includes a magnet including the first to third portions 301, 302, and 303 in the example embodiment.

The magnetic field generating body 430 includes a first surface 430a facing the magnetic sensor 60 and a second surface 430b on a side opposite to the first surface 430a. The first surface 430a includes a step-like portion 430c that includes two steps and a recessed surface recessed from the first surface 430a to the second surface 430b. The step-like portion 430c is formed at the second portion 302. A step-like portion is not formed at the first and third portions 301 and 303.

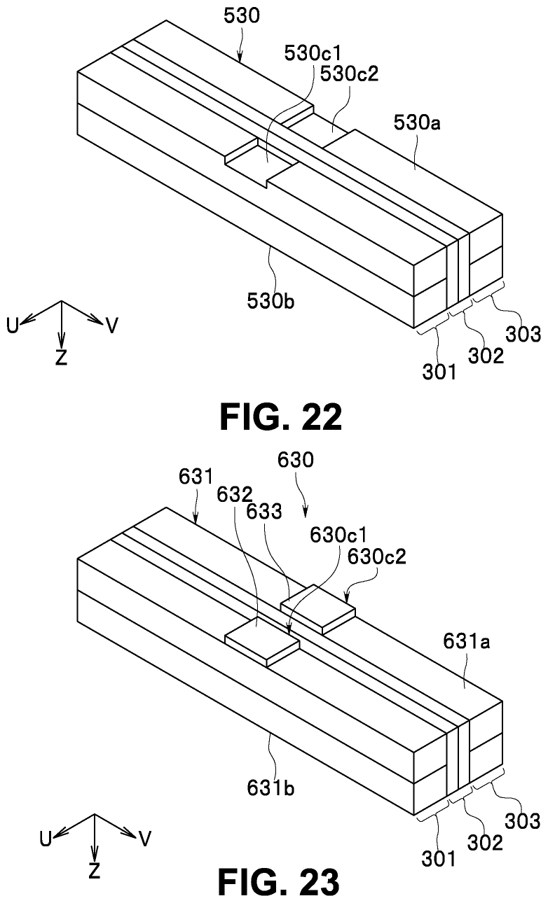

Next, with reference to FIG. 22, a magnetic field generating body 530 in the fourth modification example is described. FIG. 22 is a perspective view illustrating the magnetic field generating body 530. The magnetic field generating body 530 includes a magnet including the first to third portions 301, 302, and 303 in the example embodiment.

The magnetic field generating body 530 includes a first surface 530a facing the magnetic sensor 60 and a second surface 530b on a side opposite to the first surface 530a. The first surface 530a includes two step-like portions 530c1 and 530c2. The step-like portion 530c1 is formed at the first portion 301. The step-like portion 530c1 may include two steps, and may include a recessed surface that is recessed from the first surface 530a to the second surface 530b. The step-like portion 530c2 is formed at the third portion 303. The step-like portion 530c2 may include two steps, and may include a recessed surface that is recessed from the first surface 530a to the second surface 530b. A step-like portion is not formed at the second portion 302.

Next, with reference to FIG. 23, a magnetic field generating body 630 in the fifth modification example is described. FIG. 23 is a perspective view illustrating the magnetic field generating body 630. The magnetic field generating body 630 includes a magnet 631 and two yokes 632 and 633 formed of a soft magnetic material. The magnet 631 includes the first to third portions 301, 302, and 303 in the example embodiment.

The magnet 631 includes a first surface 631a facing the magnetic sensor 60 and a second surface 631b on a side opposite to the first surface 631a. The yoke 632 has a rectangular shape, and is arranged on a part of the first surface 631a that belongs to the first portion 301. The yoke 633 has a rectangular shape, and is arranged on a part of the first surface 631a that belongs to the third portion 303.

The magnetic field generating body 630 includes a step-like portion 630c1 including a step configured by the yoke 632 and a step-like portion 630c2 including a step configured by the yoke 633. The step-like portion 630c1 may include a protruding surface that is configured by the yoke 632 and protrudes from the first surface 631a. The step-like portion 630c2 may include a protruding surface that is configured by the yoke 633 and protrudes from the first surface 631a.

Note that the magnetic field generating body 530 in the fourth modification example, which is illustrated in FIG. 22, and the two yokes 632 and 633, which are illustrated in FIG. 23, may be combined with each other. In such a case, the yoke 632 may be arranged so as to fill the step-like portion 530c1 illustrated in FIG. 22. A portion of the yoke 632 that is not embedded in the step-like portion 530c1 forms a first step-like portion including a protruding surface that protrudes from the first surface 530a, which is illustrated in FIG. 22. Similarly, the yoke 633 may be arranged to fill the step-like portion 530c2 illustrated in FIG. 22. A portion of the yoke 633 that is not embedded in the step-like portion 530c2 forms a second step-like portion including a protruding surface that protrudes from the first surface 530a, which is illustrated in FIG. 22.

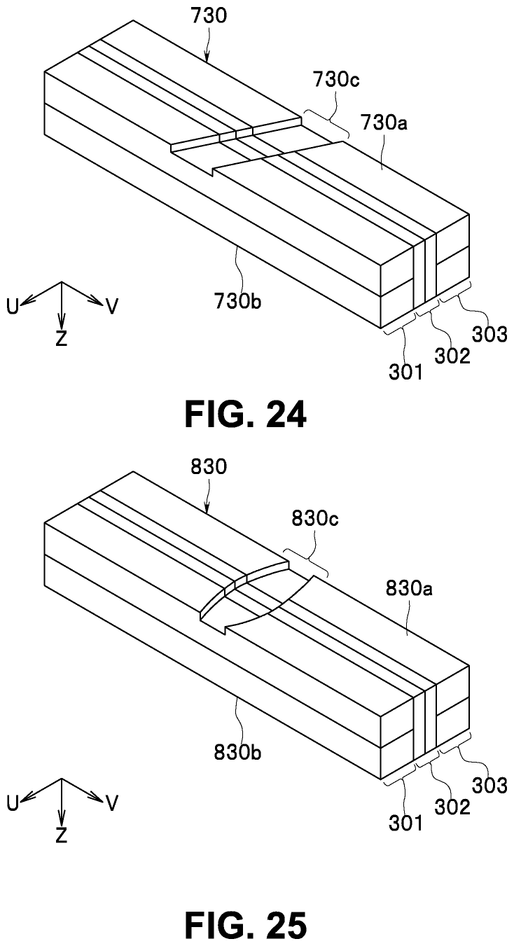

Next, with reference to FIG. 24, a magnetic field generating body 730 in the sixth modification example is described. FIG. 24 is a perspective view illustrating the magnetic field generating body 730. The magnetic field generating body 730 includes a magnet including the first to third portions 301, 302, and 303 in the example embodiment.

The magnetic field generating body 730 includes a first surface 730a facing the magnetic sensor 60 and a second surface 730b on a side opposite to the first surface 730a. The first surface 730a includes a step-like portion 730c that includes two steps and a recessed surface recessed from the first surface 730a to the second surface 730b. The step-like portion 730c is formed at each of the first to third portions 301 to 303. The longitudinal direction of the step-like portion 730c is inclined with respect to a direction parallel to the U direction.

Next, with reference to FIG. 25, a magnetic field generating body 830 in the seventh modification example is described. FIG. 25 is a perspective view illustrating the magnetic field generating body 830. The magnetic field generating body 830 includes a magnet including the first to third portions 301, 302, and 303 in the example embodiment.

The magnetic field generating body 830 includes a first surface 830a facing the magnetic sensor 60 and a second surface 830b on a side opposite to the first surface 830a. The first surface 830a includes a step-like portion 830c that includes two steps and a recessed surface recessed from the first surface 830a to the second surface 830b. The step-like portion 830c is formed at each of the first to third portion 301 to 303.

A width of the step-like portion 830c, which is a dimension of the step-like portion 830c in a direction parallel to the V direction, is largest at the second portion 302. Each of the planar shapes of the two steps of the step-like portion 830c is a curved line.

### Second Example Embodiment

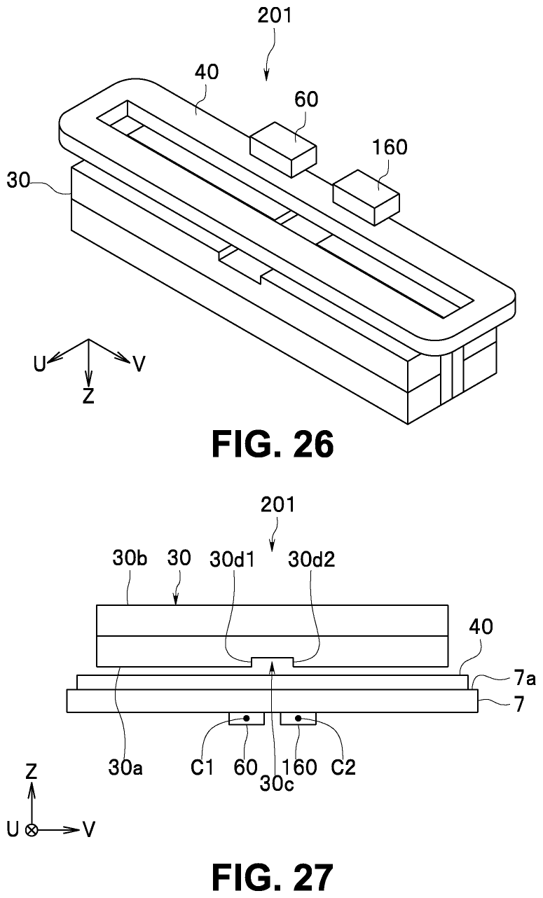

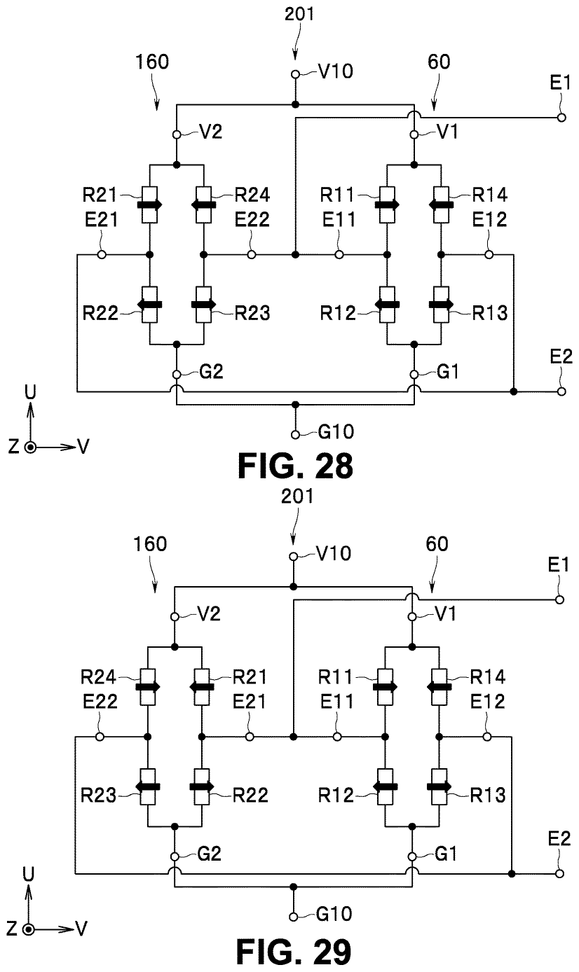

Next, with reference to FIG. 26, FIG. 27, and FIG. 28, a second example embodiment of the disclosure is described. FIG. 26 is a perspective view illustrating a magnetic sensor system according to the example embodiment. FIG. 27 is a side view illustrating the magnetic sensor system according to the example embodiment. FIG. 28 is a circuit diagram illustrating a circuit configuration of the magnetic sensor system according to the example embodiment.

A configuration of the magnetic sensor system 201 according to the example embodiment is similar to the configuration of the magnetic sensor system 101 according to the first example embodiment, except for the matters described below. The configuration of the magnetic sensor system 201 according to the example embodiment includes a magnetic sensor 160 in addition to the magnetic sensor 60.

At least a part of the magnetic sensor 160 may overlap with the step-like portion 30c of the first surface 30a of the magnetic field generating body 30 as viewed in the Z direction. In FIG. 27 the symbol C2 denotes a gravity center of the magnetic sensor 160. The gravity center C2 of the magnetic sensor 160 may match with the gravity center of the planar shape of the magnetic sensor 160 as viewed in the Z direction. The magnetic sensor 160 may be arranged so that the gravity center C2 of the magnetic sensor 160 does not overlap with the center of the step-like portion 30c in a direction parallel to the V direction as viewed in the Z direction. The magnetic sensor 160 may be arranged so as to overlap with the step 30d2 located at the end of the step-like portion 30c on the V direction side as viewed in the Z direction.

Similarly to the magnetic sensor 60, the magnetic sensor 160 includes the plurality of MR elements 50. The circuit configuration of the magnetic sensor 160 is similar to the circuit configuration of the magnetic sensor 60. In other words, the magnetic sensor 160 includes a power supply port V2 to which a voltage or a current is applied, a ground port G2 that is connected to the ground, a first output port E21, a second output port E22, and four resistor sections R21, R22, R23, and R24. The resistor section R21 is provided between the power supply port V2 and the first output port E21. The resistor section R22 is provided between the first output port E21 and the ground port G2. The resistor section R23 is provided between the second output port E22 and the ground port G2. The resistor section R24 is provided between the power supply port V2 and the second output port E22.

Each of the resistor sections R21 to R24 includes at least one MR element 50. Each of the resistor sections R21 to R24 may include the plurality of MR elements 50 connected in series. The magnetization direction of the magnetization pinned layer 52 of each of the plurality of MR elements 50 of the resistor sections R21 and R23 is the V direction. The magnetization direction of the magnetization pinned layer 52 of each of the plurality of MR elements 50 of the resistor sections R22 and R24 is the −V direction. The free layer 54 of each of the plurality of MR elements 50 may have shape anisotropy so that an easily magnetized axis direction is a direction parallel to the U direction.

The potential of the first output port E21 and the potential of the second output port E22 vary in accordance with the third component H3, which is a component of the target magnetic field in a direction parallel to the V direction. The magnetic sensor 160 generates a signal corresponding to the potential of the first output port E21 and a signal corresponding to the potential of the second output port E22, as detection signals. The detection signal has a correspondence with the third component H3 of the target magnetic field. The magnetic sensor 160 has sensitivity in a direction parallel to the V direction.

The magnetic sensor system 201 includes a power supply port V10, a ground port G10, a first output port E1, and a second output port E2. The power supply port V1 of the magnetic sensor 60 and the power supply port V2 of the magnetic sensor 160 are connected to the power supply port V10. The ground port G1 of the magnetic sensor 60 and the ground port G2 of the magnetic sensor 160 are connected to the ground port G10. The first output port E11 of the magnetic sensor 60 and the second output port E22 of the magnetic sensor 160 are connected to the first output port E1. The second output port E12 of the magnetic sensor 60 and the first output port E21 of the magnetic sensor 160 are connected to the second output port E2.

The configuration, operations, and effects of the example embodiment are otherwise the same as those of the first example embodiment.

### Modification Example

Next with reference to FIG. 29, a modification example of the circuit configuration of the magnetic sensor system 201 according to the example embodiment is described. FIG. 29 is a circuit diagram illustrating a modification example of the circuit configuration of the magnetic sensor system 201. In the modification example, the magnetization direction of the magnetization pinned layer 52 in each of the plurality of MR elements 50 of the resistor sections R21 to R24 of the magnetic sensor 160 and the connection relationship between the first and second output ports E21 and E22 of the magnetic sensor 160 and the first and second output ports E1 and E2 of the magnetic sensor system 201 are different from those in the example illustrated in FIG. 28.

In the modification example, the magnetization direction of the magnetization pinned layer 52 of each of the plurality of MR elements 50 of the resistor sections R21 and R23 is the −V direction. The magnetization direction of the magnetization pinned layer 52 of each of the plurality of MR elements 50 of the resistor sections R22 and R24 is the V direction. The first output port E21 of the magnetic sensor 160 is connected to the first output port E1, together with the first output port E11 of the magnetic sensor 60. The second output port E22 of the magnetic sensor 160 is connected to the second output port E2, together with the second output port E12 of the magnetic sensor 60.

Note that the disclosure is not limited to each of the foregoing example embodiments, and various modifications may be made thereto. For example, as long as the requirements of the claims are satisfied, shapes, numbers, and arrangements of the magnetic sensor and the magnetic field generating body are not limited to examples shown in each of the example embodiments, and are freely selected.

The magnet of the magnetic field generating body 30 may include four or more portions each including an N pole and an S pole.

The first surface 30a of the magnetic field generating body 30 may include a step-like portion including one step. In such a case, the dimension of the magnetic field generating body 30 in a direction parallel to the Z direction may be different at the end of the magnetic field generating body 30 in the V direction and at the end of the magnetic field generating body 30 in the −V direction.

The magnetic sensor system and the position detection device may be applied to an autofocus mechanism of the camera module 100. For example, in place of the magnet 10 and the magnetic sensor 20, the magnetic field generating body and the magnetic sensor of the magnetic sensor system of the disclosure may be used.

The magnetic sensor system and the position detection device may be applied to a device other than the camera module 100. In such a case, for detection of the target object whose position is to be detected, the relative position of the magnetic field generating body with respect to the magnetic sensor may vary by moving the position of the magnetic sensor in conjunction with the target object.

As described above, a magnetic sensor system according to one embodiment of the disclosure includes a magnetic field generating body configured to generate a target magnetic field, and a magnetic sensor configured to detect the target magnetic field at a detection position. The magnetic field generating body and the magnetic sensor are arrayed in a first direction, and are configured so that a relative position of the magnetic field generating body with respect to the magnetic sensor varies in a second direction intersecting with the first direction. As viewed in the first direction, the detection position is a position overlapping with the magnetic field generating body, and is a position away from both ends of the magnetic field generating body in a third direction intersecting with each of the first direction and the second direction. The magnetic field generating body is configured so that the target magnetic field includes a component in the third direction at the detection position. The magnetic sensor has sensitivity in the third direction.

In the magnetic sensor system according to the embodiment of the disclosure, the magnetic sensor may not have sensitivity in the first direction.

In the magnetic sensor system according to the embodiment of the disclosure, the magnetic field generating body may further include a first surface facing the magnetic sensor and a second surface position on a side opposite to the first surface. The first surface may include a step-like portion including at least one step.

In the magnetic sensor system according to the embodiment of the disclosure, at least a part of the magnetic sensor may overlap with the step-like portion as viewed in the first direction.

In the magnetic sensor system according to the embodiment of the disclosure, the magnetic sensor may be arranged so that a gravity center of the magnetic sensor does not overlap with a center of the step-like portion in the third direction as viewed in the first direction.

In the magnetic sensor system according to the embodiment of the disclosure, the step-like portion may include a recessed surface that is recessed from the first surface to the second surface.

In the magnetic sensor system according to the embodiment of the disclosure, the step-like portion may include a protruding surface that protrudes from the first surface.

In the magnetic sensor system according to the embodiment of the disclosure, the magnetic field generating body may include a magnet and a yoke formed of a soft magnetic material. At least a part of the step-like portion may be configured by the yoke.

In the magnetic sensor system according to the embodiment of the disclosure, the magnetic field generating body may include a magnet including an N pole and an S pole arrayed in the second direction.

In the magnetic sensor system according to the embodiment of the disclosure, the magnetic field generating body may include a magnet including a plurality of portions each including an N pole and an S pole. The plurality of portions may be arranged along the second direction. Among the plurality of portions, a direction in which the N pole and the S pole are arranged in one of two adjacent portions may be different from a direction in which the N pole and the S pole are arranged in the other of the two adjacent portions.

The magnetic sensor system according to the embodiment of the disclosure may further include a coil configured to vary the relative position of the magnetic field generating body with respect to the magnetic sensor. The magnetic sensor may be arranged to overlap with a region surrounded by the coil as viewed in the first direction.

In the magnetic sensor system according to the embodiment of the disclosure, the relative position of the magnetic field generating body with respect to the magnetic sensor may have a correspondence with a position of a target object whose position is variable.

A position detection device according to one embodiment of the disclosure is a position detection device for detecting a position of a target object whose position is variable. The position detection device according to one embodiment of the disclosure includes a magnetic sensor system including a magnetic field generating body configured to generate a target magnetic field and a magnetic sensor configured to detect the target magnetic field at a detection position, and the target object. The magnetic field generating body and the magnetic sensor are arrayed in a first direction, and are configured so that a relative position of the magnetic field generating body with respect to the magnetic sensor varies in a second direction intersecting with the first direction. The relative position of the magnetic field generating body with respect to the magnetic sensor has a correspondence with the target object. As viewed in the first direction, the detection position is a position overlapping with the magnetic field generating body, and is a position away from both ends of the magnetic field generating body in a third direction intersecting with each of the first direction and the second direction. The magnetic field generating body is configured so that the target magnetic field includes a component in the third direction at the detection position. The magnetic sensor has sensitivity in the third direction.

In the magnetic sensor system and the position detection device of the disclosure, the magnetic field generating body and the magnetic sensor are arrayed in a first direction, and are configured so that a relative position of the magnetic field generating body with respect to the magnetic sensor varies in a second direction intersecting with the first direction. The magnetic field generating body is configured so that the target magnetic field includes a component in the third direction at the detection position. The magnetic sensor has sensitivity in the third direction. With this, according to the disclosure, the target magnetic field can be detected without being affected by a magnetic field other than the target magnetic field.

Obviously, various aspects and modification examples of the disclosure can be practiced in the light of the foregoing descriptions. Thus, within the scope of the appended claims and equivalents thereof, the disclosure can be practiced in embodiments other than the foregoing example embodiments.

1. A magnetic sensor system comprising:
a magnetic field generating body configured to generate a target magnetic field; and
a magnetic sensor configured to detect the target magnetic field at a detection position, wherein
the magnetic field generating body and the magnetic sensor are arrayed in a first direction, and are configured so that a relative position of the magnetic field generating body with respect to the magnetic sensor varies in a second direction intersecting with the first direction,
as viewed in the first direction, the detection position is a position overlapping with the magnetic field generating body, and is a position away from both ends of the magnetic field generating body in a third direction intersecting with each of the first direction and the second direction,
the magnetic field generating body is configured so that the target magnetic field includes a component in the third direction at the detection position, and
the magnetic sensor has sensitivity in the third direction.

2. The magnetic sensor system according to claim 1, wherein the magnetic sensor does not have sensitivity in the first direction.

3. The magnetic sensor system according to claim 1, wherein
the magnetic field generating body further includes a first surface facing the magnetic sensor and a second surface position on a side opposite to the first surface; and
the first surface includes a step-like portion including at least one step.

4. The magnetic sensor system according to claim 3, wherein at least a part of the magnetic sensor overlaps with the step-like portion as viewed in the first direction.

5. The magnetic sensor system according to claim 3, wherein the magnetic sensor is arranged so that a gravity center of the magnetic sensor does not overlap with a center of the step-like portion in the third direction as viewed in the first direction.

6. The magnetic sensor system according to claim 3, wherein the step-like portion includes a recessed surface that is recessed from the first surface to the second surface.

7. The magnetic sensor system according to claim 3, wherein the step-like portion includes a protruding surface that protrudes from the first surface.

8. The magnetic sensor system according to claim 3, wherein
the magnetic field generating body includes a magnet and a yoke formed of a soft magnetic material; and
at least a part of the step-like portion is configured by the yoke.

9. The magnetic sensor system according to claim 1, wherein the magnetic field generating body includes a magnet including an N pole and an S pole arrayed in the second direction.

10. The magnetic sensor system according to claim 1, wherein
the magnetic field generating body includes a magnet including a plurality of portions each including an N pole and an S pole,
the plurality of portions are arranged along the second direction, and
among the plurality of portions, a direction in which the N pole and the S pole are arranged in one of two adjacent portions is different from a direction in which the N pole and the S pole are arranged in the other of the two adjacent portions.

11. The magnetic sensor system according to claim 1, further comprising a coil configured to vary the relative position of the magnetic field generating body with respect to the magnetic sensor.

12. The magnetic sensor system according to claim 11, wherein the magnetic sensor is arranged to overlap with a region surrounded by the coil as viewed in the first direction.

13. The magnetic sensor system according to claim 1, wherein the relative position of the magnetic field generating body with respect to the magnetic sensor has a correspondence with a position of a target object whose position is variable.

14. A position detection device for detecting a position of a target object whose position is variable, the position detection device comprising:
a magnetic sensor system including a magnetic field generating body configured to generate a target magnetic field and a magnetic sensor configured to detect the target magnetic field at a detection position; and
the target object, wherein
the magnetic field generating body and the magnetic sensor are arrayed in a first direction, and are configured so that a relative position of the magnetic field generating body with respect to the magnetic sensor varies in a second direction intersecting with the first direction,
the relative position of the magnetic field generating body with respect to the magnetic sensor has a correspondence with the target object,
as viewed in the first direction, the detection position is a position overlapping with the magnetic field generating body, and is a position away from both ends of the magnetic field generating body in a third direction intersecting with each of the first direction and the second direction,
the magnetic field generating body is configured so that the target magnetic field includes a component in the third direction at the detection position, and
the magnetic sensor has sensitivity in the third direction.
